(19) United States
(12) Patent Application Publication
(10) Pub. No.: US 2025/0140713 A1
(43) Pub. Date: May 1, 2025

(54) MOISTURE RESISTANT SEMICONDUTOR DEVICE

(71) Applicant: Microchip Technology Incorporated, Chandler, AZ (US)

(72) Inventors: Shesh Mani Pandey, Gilbert, AZ (US); Randy L. Yach, Phoenix, AZ (US); Bruce Odekirk, Portland, OR (US); George Dorman, Chandler, AZ (US); Gary Frazier, Divide, CO (US)

(73) Assignee: Microchip Technology Incorporated, Chandler, AZ (US)

(21) Appl. No.: 18/673,383

(22) Filed: May 24, 2024

Related U.S. Application Data
(60) Provisional application No. 63/545,736, filed on Oct. 25, 2023.

(51) Int. Cl. H01L 23/00; H01L 23/31; H01L 29/06

(52) U.S. Cl. CPC H01L 23/564; H01L 23/3192; H10D 62/107

(57) ABSTRACT

A moisture resistant semiconductor device may include a substrate and a plurality of terminations in the substrate of the semiconductor device, wherein the plurality of terminations are laterally adjacent to an active region of the semiconductor device. A first insulating layer which overlays the plurality of terminations and the substrate. A trench into the substrate located laterally beyond an edge of the plurality of terminations. A contact layer which overlays the first insulating layer. A second insulating layer which overlays the contact layer. The second insulating layer which overlays the trench. A third insulating layer which overlays the second insulating layer.

### CROSS-REFERENCE TO RELATED APPLICATION

The present application claims priority to U.S. Provisional Patent Application No. 63/545,736, filed on Oct. 25, 2023, the contents of which are hereby incorporated by reference in their entirety.

### TECHNICAL FIELD

The present disclosure relates generally to semiconductor devices, and more specifically to a semiconductor device designed to reduce the amount of moisture that may enter the interface between the field oxide layer and the substrate.

### SUMMARY

According to an aspect of one or more examples, there is provided a moisture resistant semiconductor device. The semiconductor device may include a substrate, a plurality of terminations in the substrate of the semiconductor device, wherein the plurality of terminations are laterally adjacent to an active region of the semiconductor device, a first insulating layer which overlays the plurality of terminations and the substrate, a trench into the substrate located laterally beyond an edge of the plurality of terminations, a contact layer which overlays the first insulating layer, a second insulating layer which overlays the contact layer, the second insulating layer which overlays the trench, and a third insulating layer which overlays the second insulating layer. The first insulating layer may comprise a field oxide layer. The contact layer may comprise an oxynitride layer or a silicon oxynitride layer. The second insulating layer can comprise a nitride layer. The third insulating layer may comprise a polyimide layer.

According to an aspect of one or more examples, there is provided a moisture resistant semiconductor device. The semiconductor device may include a substrate, a plurality of terminations in the substrate of the semiconductor device, wherein the plurality of terminations are laterally adjacent to an active region of the semiconductor device, a first insulating layer which overlays the plurality of terminations and the substrate, a trench into the substrate located laterally beyond an edge of the plurality of terminations, a contact layer which overlays the first insulating layer and which overlays the trench, a second insulating layer which overlays the contact layer, and a third insulating layer which overlays the second insulating layer. The first insulating layer may comprise a field oxide layer. The contact layer may comprise an oxynitride layer or a silicon oxynitride layer. The second insulating layer can comprise a nitride layer. The third insulating layer may comprise a polyimide layer.

According to an aspect of one or more examples, there is provided a moisture resistant semiconductor device. The semiconductor device may include a substrate, a plurality of terminations in the substrate of the semiconductor device, wherein the plurality of terminations are laterally adjacent to an active region of the semiconductor device, a first insulating layer which overlays the plurality of terminations and the substrate, a plurality of recesses into the substrate located laterally beyond an edge of the plurality of terminations, a contact layer which overlays the first insulating layer, a second insulating layer which overlays the contact layer and which overlays the plurality of recesses, and a third insulating layer which overlays the second insulating layer. The first insulating layer may comprise a field oxide layer. The contact layer may comprise an oxynitride layer or a silicon oxynitride layer. The second insulating layer can comprise a nitride layer. The third insulating layer may comprise a polyimide layer.

According to an aspect of one or more examples, there is provided a moisture resistant semiconductor device. The semiconductor device may include a substrate, a plurality of terminations in the substrate of the semiconductor device, wherein the plurality of terminations are laterally adjacent to an active region of the semiconductor device, a first insulating layer which overlays the plurality of terminations and the substrate, a plurality of recesses into the substrate located laterally beyond an edge of the plurality of terminations, a contact layer which overlays the first insulating layer and which overlays the plurality of recesses, a second insulating layer which overlays the contact layer, and a third insulating layer which overlays the second insulating layer. The first insulating layer may comprise a field oxide layer. The contact layer may comprise an oxynitride layer or a silicon oxynitride layer. The second insulating layer can comprise a nitride layer. The third insulating layer may comprise a polyimide layer.

### BRIEF DESCRIPTION OF DRAWINGS

FIG. 1 shows a cross-sectional view of a moisture resistant semiconductor device according to one or more examples wherein a trench may be etched into the substrate to a depth that is greater than the depth of a first insulating layer in the vertical direction and a second insulating layer may be formed to extend vertically downward to cover the interface between the substrate and the first insulating layer.

FIG. 2 shows a cross-sectional view of a moisture resistant semiconductor device according to one or more examples wherein a trench may be etched into the substrate to a depth that is greater than the depth of a first insulating layer in the vertical direction and a contact layer may be formed to extend vertically downward to cover the interface between the substrate and the first insulating layer.

FIG. 3 shows a cross-sectional view of a moisture resistant semiconductor device according to one or more examples wherein a plurality of recesses are etched into the substrate to a depth that is greater than the depth of the first insulating layer in the vertical direction and a second insulating layer may be formed to extend vertically downward to cover the interface between the substrate and the first insulating layer.

FIG. 4 shows a cross-sectional view of a moisture resistant semiconductor device according to one or more examples wherein a plurality of recesses are etched into the substrate to a depth that is greater than the depth of the first insulating layer in the vertical direction and a contact layer may be formed to extend vertically downward to cover the interface between the substrate and the first insulating layer.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Semiconductor devices rely on one or more p-n junctions between a p-type semiconductor and an n-type semiconductor. An active region of the junction emits an electric field in a lateral direction, which can negatively affect performance of the device. To reduce the electric field emitted in the lateral direction, guard rings or terminations may be formed in the substrate of the semiconductor device. For example, a semiconductor device with an n-type substrate may have a p-well that forms an active region p-n junction with the n-type substrate. A plurality of p-type terminations may be formed laterally adjacent to the active region to reduce the electric field that is emitted laterally. A field oxide layer is formed on the substrate, and may extend laterally beyond the last termination of the plurality of terminations. However, in high humidity environments, moisture may enter the interface between the field oxide layer and the substrate, which may negatively affect performance of the device. Accordingly, there is a need to reduce moisture that may enter the interface between the device substrate and the field oxide layer.

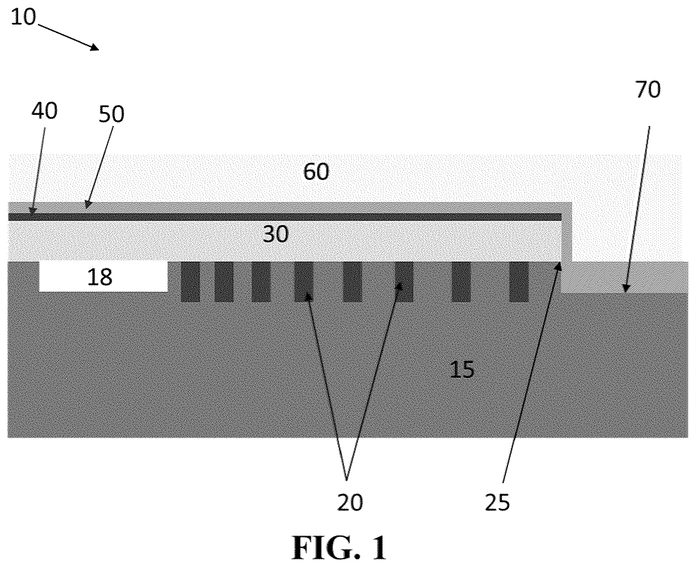

FIG. 1 shows cross-sectional view of a semiconductor device 10 according to one or more examples. The semiconductor device 10 may include a substrate 15, which may be made of a first type semiconductor material such as silicon or silicon carbide. A second type semiconductor material may be implanted in the first type substrate 15 to create a p-n junction that forms an active region 18 of the semiconductor device 10. If the first type is an n-type doped semiconductor material then the second type is a p-type doped semiconductor material. If the first type is a p-type doped semiconductor material then the second type is an n-type doped semiconductor material. A plurality of second type terminations 20 may be implanted to reduce the electric field emitted from the active region 18 in the lateral direction. As shown in FIG. 1, the plurality of terminations 20 may be formed as concentric rings, spaced at respective increasing radial distances from the active region 18, around the active region 18. A first insulating layer 30 such as a field oxide layer may be formed on the substrate 15 overlapping the active region 18 and the plurality of terminations 20. The first insulating layer 30, in the example semiconductor device of FIG. 1, may extend laterally beyond the last termination of the plurality of terminations 20 that is farthest from the active region 18. A contact layer 40 (such as an oxynitride or silicon oxynitride, though other materials may be used) may be formed which overlays the first insulating layer 30. At the lateral edge of the first insulating layer 30, an interface 25 between the first insulating layer 30 and the substrate 15 may be susceptible to moisture in high humidity environments. To reduce the possibility of moisture entering the interface 25 between the first insulating layer 30 and the substrate 15, a portion of the substrate 15 located laterally beyond an edge of the first insulating layer 30 may have a trench 70 etched into the substrate 15 to a depth that is greater than the depth of the first insulating layer 30 in the vertical direction. A second insulating layer 50 (which may be formed of nitride, though other insulating materials may be used) may be formed which overlays the trench 70 that was formed in the substrate 15 and which overlays the contact layer 40. As shown in the example shown in FIG. 1, the second insulating layer 50 may be formed to extend vertically downward to cover the interface 25 between the substrate 15 and the first insulating layer 30.

According to the example shown in FIG. 1, a third insulating layer 60 may be formed on the second insulating layer 50. The third insulating layer 60 may be formed of polyimide, though other insulating materials may be used. According to one or more examples, the third insulating layer 60 may also extend vertically downward to cover the interface 25 between the substrate 15 and the first insulating layer 30, i.e. to cover the second insulating layer 50 in the region where the second insulating layer 50 covers the interface 25 between the substrate 15 and the first insulating layer 30. The third insulating layer 60 may also extend laterally over the trench 70 in the substrate 15 located laterally beyond the edge of the first insulating layer 30. Moreover, although not shown in the cross-sectional view of FIG. 1, the second insulating layer 50 and the third insulating layer 60 may extend in a lateral direction, a vertical direction, and a depth direction to respectively encompass the interface 25 between the first insulating layer 30 and the substrate 15 in three dimensions. Because the second insulating layer 50 and third insulating layer 60 cover the interface 25 between the first insulating layer 30 and the substrate 15, the amount of external moisture that may enter the interface 25 may be reduced.

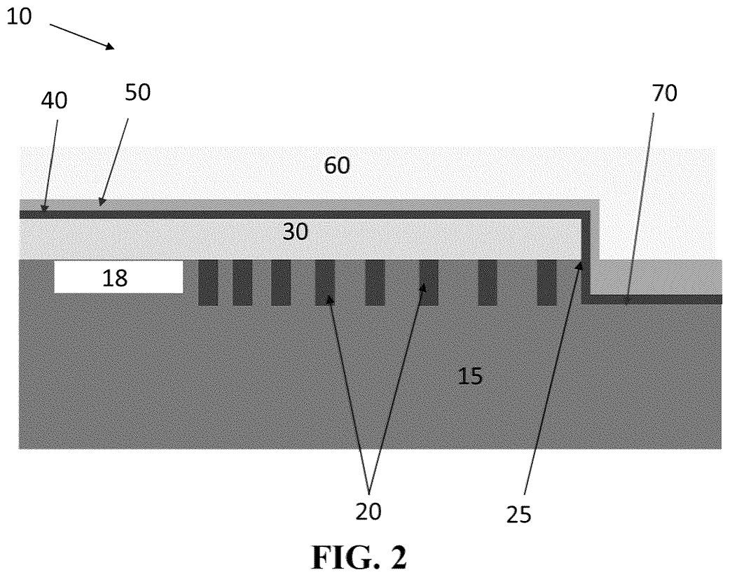

FIG. 2 shows cross-sectional view of a semiconductor device 10 according to one or more examples. The semiconductor device 10 may include a substrate 15, which may be made of a first type semiconductor material such as silicon or silicon carbide. A second type semiconductor material may be implanted in the first type substrate 15 to create a p-n junction that forms an active region 18 of the semiconductor device 10. If the first type is an n-type doped semiconductor material then the second type is a p-type doped semiconductor material. If the first type is a p-type doped semiconductor material then the second type is an n-type doped semiconductor material. A plurality of second type terminations 20 may be implanted to reduce the electric field emitted from the active region 18 in the lateral direction. As shown in FIG. 2, the plurality of terminations 20 may be formed as concentric rings around the active region 18. A first insulating layer 30 such as a field oxide layer may be formed on the substrate 15 overlapping the active region 18 and the plurality of terminations 20. The first insulating layer 30, in the example semiconductor device of FIG. 2, may extend laterally beyond the last termination of the plurality of terminations 20 that is farthest from the active region 18. At the lateral edge of the first insulating layer 30, an interface 25 between the first insulating layer 30 and the substrate 15 may be susceptible to moisture in high humidity environments. To reduce the possibility of moisture entering the interface 25 between the first insulating layer 30 and the substrate 15, a portion of the substrate 15 located laterally beyond an edge of the first insulating layer 30 may have a trench 70 etched into the substrate 15 to a depth that is greater than the depth of the first insulating layer 30 in the vertical direction. A contact layer 40 (such as an oxynitride or silicon oxynitride, though other materials may be used) may be formed which overlays the first insulating layer 30 and which overlays the trench 70 that was formed in the substrate 15. As shown in the example shown in FIG. 2, the contact layer 40 may be formed to extend vertically downward to cover the interface 25 between the substrate 15 and the first insulating layer 30. A second insulating layer 50 (which may be formed of nitride, though other insulating materials may be used) may be formed which overlays the contact layer 40. As shown in the example shown in FIG. 2, the second insulating layer 50 may be formed to extend vertically downward to cover the interface 25 between the substrate 15 and the first insulating layer 30, i.e. to cover the contact layer 40 in the region where the contact layer 40 covers the interface 25 between the substrate 15 and the first insulating layer 30.

According to the example shown in FIG. 2, a third insulating layer 60 may be formed on the second insulating layer 50. The third insulating layer 60 may be formed of polyimide, though other insulating materials may be used. According to one or more examples, the third insulating layer 60 may also extend vertically downward to cover the interface 25 between the substrate 15 and the first insulating layer 30, i.e. to cover the second insulating layer 50, which covers the contact layer 40, in the region where the contact layer 40 covers the interface 25 between the substrate 15 and the first insulating layer 30. The third insulating layer 60 may also extend laterally over the trench 70 in the substrate 15 located laterally beyond the edge of the first insulating layer 30. Moreover, although not shown in the cross-sectional view of FIG. 2, the contact layer 40, the second insulating layer 50 and the third insulating layer 60 may extend in a lateral direction, a vertical direction, and depth direction to respectively encompass the interface 25 between the first insulating layer 30 and the substrate 15 in three dimensions. Because the contact layer 40, the second insulating layer 50 and the third insulating layer 60 cover the interface 25 between the first insulating layer 30 and the substrate 15, the amount of external moisture that may enter the interface 25 may be reduced.

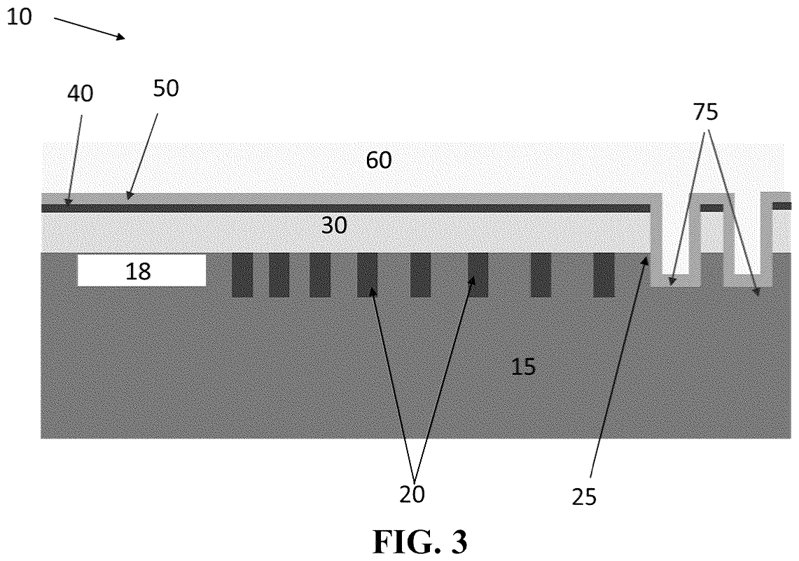

FIG. 3 shows cross-sectional view of a semiconductor device 10 according to one or more examples. The semiconductor device 10 may include a substrate 15, which may be made of a first type semiconductor material such as silicon or silicon carbide. A second type semiconductor material may be implanted in the first type substrate 15 to create a p-n junction that forms an active region 18 of the semiconductor device 10. If the first type is an n-type doped semiconductor material then the second type is a p-type doped semiconductor material. If the first type is a p-type doped semiconductor material then the second type is an n-type doped semiconductor material. A plurality of second type terminations 20 may be implanted to reduce the electric field emitted from the active region 18 in the lateral direction. As shown in FIG. 3, the plurality of terminations 20 may be formed as concentric rings around active region 18. A first insulating layer 30 such as a field oxide layer may be formed on the substrate 15 overlapping the active region 18 and the plurality of terminations 20. The first insulating layer 30, in the example semiconductor device of FIG. 3, may extend laterally beyond the last termination of the plurality of terminations 20 that is farthest from the active region 18. A contact layer 40 (such as an oxynitride or silicon oxynitride, though other materials may be used) may be formed which overlays the first insulating layer 30. At the lateral edge of the first insulating layer 30, an interface 25 between the first insulating layer 30 and the substrate 15 may be susceptible to moisture in high humidity environments. To reduce the possibility of moisture entering the interface 25 between the first insulating layer 30 and the substrate 15, a portion of the substrate 15 located laterally beyond an edge of the first insulating layer 30 may have a plurality of recesses 75 etched into the substrate 15 to a depth that is greater than the depth of the first insulating layer 30 in the vertical direction. A second insulating layer 50 (which may be formed of nitride, though other insulating materials may be used) may be formed which overlays the plurality of recesses 75 that was formed in the substrate 15 and which overlays the contact layer 40. As shown in the example shown in FIG. 3, the second insulating layer 50 may be formed to extend vertically downward to cover the interface 25 between the substrate 15 and the first insulating layer 30.

According to the example shown in FIG. 3, a third insulating layer 60 may be formed on the second insulating layer 50. The third insulating layer 60 may be formed of polyimide, though other insulating materials may be used. According to one or more examples, the third insulating layer 60 may also extend vertically downward to cover the interface 25 between the substrate 15 and the first insulating layer 30, i.e. to cover the second insulating layer 50 in the region where the second insulating layer 50 covers the interface 25 between the substrate 15 and the first insulating layer 30. The third insulating layer 60 may also extend laterally to be formed over the plurality of recesses 75 in the substrate 15 located laterally beyond the edge of the first insulating layer 30. Moreover, although not shown in the cross-sectional view of FIG. 3, the second insulating layer 50 and the third insulating layer 60 may extend in a lateral direction, a vertical direction, and depth direction to respectively encompass the interface 25 between the first insulating layer 30 and the substrate 15 in three dimensions. Because the second insulating layer 50 and third insulating layer 60 cover the interface 25 between the first insulating layer 30 and the substrate 15, the amount of external moisture that may enter the interface 25 may be reduced.

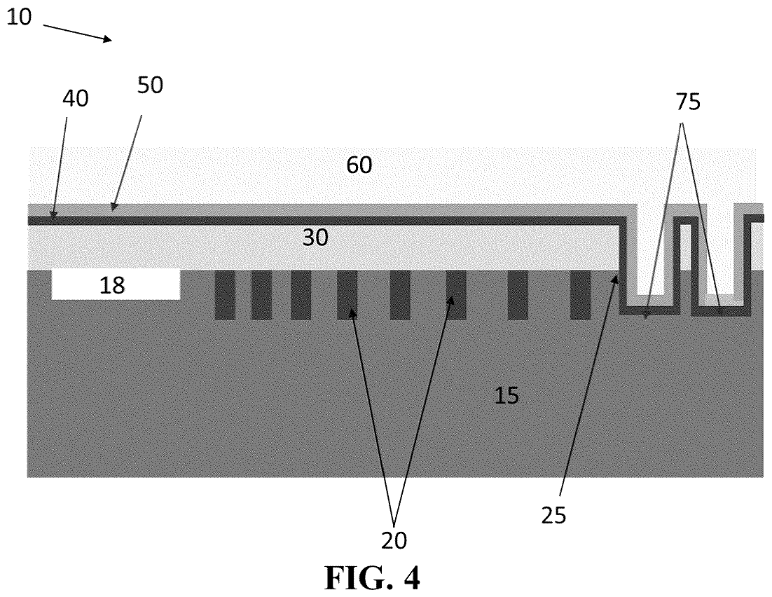

FIG. 4 shows cross-sectional view of a semiconductor device 10 according to one or more examples. The semiconductor device 10 may include a substrate 15, which may be made of a first type semiconductor material such as silicon or silicon carbide. A second type semiconductor material may be implanted in the first type substrate 15 to create a p-n junction that forms an active region 18 of the semiconductor device 10. If the first type is an n-type doped semiconductor material then the second type is a p-type doped semiconductor material. If the first type is a p-type doped semiconductor material then the second type is an n-type doped semiconductor material. A plurality of second type terminations 20 may be implanted to reduce the electric field emitted from the active region 18 in the lateral direction. As shown in FIG. 4, the plurality of terminations 20 may be formed as concentric rings around the active region 18. A first insulating layer 30 such as a field oxide layer may be formed on the substrate 15 overlapping the active region 18 and the plurality of terminations 20. The first insulating layer 30, in the example semiconductor device of FIG. 4, may extend laterally beyond the last termination of the plurality of terminations 20 that is farthest from the active region 18. At the lateral edge of the first insulating layer 30, an interface 25 between the first insulating layer 30 and the substrate 15 may be susceptible to moisture in high humidity environments. To reduce the possibility of moisture entering the interface 25 between the first insulating layer 30 and the substrate 15, a portion of the substrate 15 located laterally beyond an edge of the first insulating layer 30 may have a plurality of recesses 75 etched into the substrate 15 to a depth that is greater than the depth of the first insulating layer 30 in the vertical direction. A contact layer 40 (such as an oxynitride or silicon oxynitride, though other materials may be used) may be formed which overlays the first insulating layer 30 and which overlays the plurality of recesses 75 that were formed in the substrate 15. As shown in the example shown in FIG. 4, the contact layer 40 may be formed to extend vertically downward to cover the interface 25 between the substrate 15 and the first insulating layer 30. A second insulating layer 50 (which may be formed of nitride, though other insulating materials may be used) may be formed which overlays the contact layer 40. As shown in the example shown in FIG. 4, the second insulating layer 50 may be formed to extend vertically downward to cover the interface 25 between the substrate 15 and the first insulating layer 30, i.e. to cover the contact layer 40 in the region where the contact layer 40 covers the interface 25 between the substrate 15 and the first insulating layer 30.

According to the example shown in FIG. 4, a third insulating layer 60 may be formed on the second insulating layer 50. The third insulating layer 60 may be formed of polyimide, though other insulating materials may be used. According to one or more examples, the third insulating layer 60 may also extend vertically downward to cover the interface 25 between the substrate 15 and the first insulating layer 30, i.e. to cover the second insulating layer 50, which covers the contact layer 40, in the region where the contact layer 40 covers the interface 25 between the substrate 15 and the first insulating layer 30. The third insulating layer 60 may also extend laterally to be formed over the plurality of recesses 75 in the substrate 15 located laterally beyond the edge of the first insulating layer 30. Moreover, although not shown in the cross-sectional view of FIG. 4, the contact layer 40, the second insulating layer 50 and the third insulating layer 60 may extend in a lateral direction, a vertical direction, and depth direction to respectively encompass the interface 25 between the first insulating layer 30 and the substrate 15 in three dimensions. Because the contact layer 40, the second insulating layer 50 and third insulating layer 60 cover the interface 25 between the first insulating layer 30 and the substrate 15, the amount of external moisture that may enter the interface 25 may be reduced.

Various examples have been disclosed herein, in connection with the above description and the drawings. It will be understood that it would be unduly repetitious to literally describe and illustrate every combination and subcombination of these examples. Accordingly, all examples can be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A moisture resistant semiconductor device comprising:
a substrate;
a plurality of terminations in the substrate of the semiconductor device, wherein the plurality of terminations are laterally adjacent to an active region of the semiconductor device;
a first insulating layer which overlays the plurality of terminations and the substrate;
a trench into the substrate located laterally beyond an edge of the plurality of terminations;
a contact layer which overlays the first insulating layer;
a second insulating layer which overlays the contact layer, the second insulating layer overlays the trench; and
a third insulating layer which overlays the second insulating layer.

2. The semiconductor device of claim 1, wherein the first insulating layer comprises a field oxide layer.

3. The semiconductor device of claim 1, wherein the contact layer comprises an oxynitride layer or a silicon oxynitride layer.

4. The semiconductor device of claim 1, wherein the second insulating layer comprises a nitride layer.

5. The semiconductor device of claim 1, wherein the third insulating layer comprises a polyimide layer.

6. A moisture resistant semiconductor device comprising:
a substrate;
a plurality of terminations in the substrate of the semiconductor device, wherein the plurality of terminations are laterally adjacent to an active region of the semiconductor device;
a first insulating layer which overlays the plurality of terminations and the substrate;
a trench into the substrate located laterally beyond an edge of the plurality of terminations;
a contact layer which overlays the first insulating layer and which overlays the trench;
a second insulating layer which overlays the contact layer; and
a third insulating layer which overlays the second insulating layer.

7. The semiconductor device of claim 6, wherein the first insulating layer comprises a field oxide layer.

8. The semiconductor device of claim 6, wherein the contact layer comprises an oxynitride layer or a silicon oxynitride layer.

9. The semiconductor device of claim 6, wherein the second insulating layer comprises a nitride layer.

10. The semiconductor device of claim 6, wherein the third insulating layer comprises a polyimide layer.

11. A moisture resistant semiconductor device comprising:
a substrate;
a plurality of terminations in the substrate of the semiconductor device, wherein the plurality of terminations are laterally adjacent to an active region of the semiconductor device;
a first insulating layer which overlays the plurality of terminations and the substrate;
a plurality of recesses into the substrate located laterally beyond an edge of the plurality of terminations;
a contact layer which overlays the first insulating layer;
a second insulating layer which overlays the contact layer and which overlays the plurality of recesses; and
a third insulating layer which overlays the second insulating layer.

12. The semiconductor device of claim 11, wherein the first insulating layer comprises a field oxide layer.

13. The semiconductor device of claim 11, wherein the contact layer comprises an oxynitride layer or a silicon oxynitride layer.

14. The semiconductor device of claim 11, wherein the second insulating layer comprises a nitride layer.

15. The semiconductor device of claim 11, wherein the third insulating layer comprises a polyimide layer.

16. A moisture resistant semiconductor device comprising:
a substrate;
a plurality of terminations in the substrate of the semiconductor device, wherein the plurality of terminations are laterally adjacent to an active region of the semiconductor device;
a first insulating layer which overlays the plurality of terminations and the substrate;
a plurality of recesses into the substrate located laterally beyond an edge of the plurality of terminations;
a contact layer which overlays the first insulating layer and which overlays the plurality of recesses;
a second insulating layer which overlays the contact layer; and
a third insulating layer which overlays the second insulating layer.

17. The semiconductor device of claim 16, wherein the first insulating layer comprises a field oxide layer.

18. The semiconductor device of claim 16, wherein the contact layer comprises an oxynitride layer or a silicon oxynitride layer.

19. The semiconductor device of claim 16, wherein the second insulating layer comprises a nitride layer.

20. The semiconductor device of claim 16, wherein the third insulating layer comprises a polyimide layer.
